(19) United States
(12) Patent Application Publication
(10) Pub. No.: US 2011/0175189 A1
(43) Pub. Date: Jul. 21, 2011

(54) SOLID-STATE IMAGE SENSOR MANUFACTURING METHOD AND A SOLID-STATE IMAGE SENSOR

(76) Inventor: Noriaki SUZUKI, Kyoto (JP)

(21) Appl. No.: 13/006,491

(22) Filed: Jan. 14, 2011

(30) Foreign Application Priority Data
Jan. 20, 2010 (JP) 2010-010257

(51) Int. Cl. H01L 27/146; H01L 31/18

(52) U.S. Cl. 257/443; 438/73; 257/E27.133; 257/E31.001

(57) ABSTRACT

In the solid-state image sensor manufacturing method according to the present invention, metal silicide films comprising of at least one of cobalt silicide film, nickel silicide film, and titanium silicide film having similar specific resistances to metal films are selectively formed on the top faces (whole surfaces for example) of charge-transfer electrodes. The kind of manufacturing method realizes a solid-state image sensor which keeps the charge-transfer electrodes at low resistance, can operate at a high speed, and is highly sensitive even if the width of those electrodes is reduced.

### CROSS REFERENCE TO RERATED APPLICATION

The disclosure of Japanese Patent Application No. 2010-010257 filed Jan. 20, 2010 including specification, drawings and claims is incorporated herein by reference in its entirety.

### BACKGROUND OF THE INVENTION

1. Field of the Invention

The present invention relates to a solid-state image sensor manufacturing method and a solid-state image sensor structure, and in particular to a solid-state image sensor having a charge-transfer electrode of a single-layer structure.

2. Description of the Related Art

Among solid-state image sensors, CCD-type solid-state image sensors (hereafter referred to as CCDs) have a structure wherein many charge-transfer electrodes which transfer image signal charges generated by incident light are arranged adjoining one another in an array. In such a structure, it is necessary to make the space between adjoining charge-transfer electrodes small enough to transfer signal charges efficiently. In the past the mainstream method to achieve it was to form a double-layer structure by arranging charge-transfer electrodes so as to overlap partially with one another via a thin insulating film.

However, in recent years along with the progress in fine processing technology, forming a groove pattern having a width of 0.2 μm or less has become possible. In CCDs also, the mainstream has become a single-layer electrode structure wherein a multiple charge-transfer electrode pattern is formed with a narrow interval and a single electrode layer (see Japanese patent application No. 2005-353685 (Prior Art Document 1) for example). CCDs of a single-layer electrode structure have an advantage of having a small inter-electrode capacitance because there is no overlapping part between charge-transfer electrodes. In addition, although a light-blocking layer formed in an upper layer of a charge-transfer electrode is usually biased with a specified voltage such as the ground potential, because a single-layer electrode structure has little surface steps, it has an advantage that a withstand voltage can be easily secured between the charge-transfer electrodes and the light-blocking layer.

FIG. 5 is a representative outline planar structural diagram of a solid-state image sensor (CCD). A solid-state image sensor 20 has an imaging region 21 installed, the imaging region 21 comprises photodiodes 22 for photoelectrically converting incident light, vertical transfer units 23 for vertically transferring signal charges generated in the photodiodes 22, and a horizontal transfer unit 24 for horizontally transferring signal charges transferred by the vertical transfer units 23. Multiple photodiodes 22 are arranged in a matrix form, and the vertical transfer units 23 are placed between the columns of the photodiodes 22. Although no charge-transfer electrode is shown in FIG. 5, one piece of charge-transfer electrode extends horizontally from the right-edge region to the left-edge region in the imaging region. Signal charges transferred through the horizontal transfer unit 24 are output as electric signals via an output amplifier 25.

However, in a CCD wherein the imaging region 21 occupies a relatively large area, because the horizontal length of the imaging region 21 is large, the length of the charge-transfer electrodes also becomes large. Therefore, there occurs a propagation delay in driving pulse signals applied to each of the charge-transfer electrodes with a different phase, bad charge transfer may become a problem. If the charge-transfer electrodes are made of a silicon-system films having a sheet resistance value of several ten Ω/□, this propagation delay signifies the following. It is the difference between the time for the driving pulse signal to be transmitted from the driving pulse signal input terminal to the vertical transfer unit 23 closer to the bus line installed outside the imaging region 21 and the time it is transmitted to the vertical transfer unit 23 farther from the bus line.

In recent years, in order to deal with rapid-fire photographing and HD (high-definition) videos by imaging equipment, further speediness is demanded of CCDs. In addition, from the viewpoint of sensitivity enhancement of solid-state image sensors, in order to reduce the invalid area which does not contribute to incident light detection and secure a wide photodiode area, charge-transfer electrodes have been progressively made finer, which increases the resistance values of the charge-transfer electrodes more and more. Because the problems of said propagation delay will become significant along with the progress of such an activity, resistance reduction of charge-transfer electrodes is regarded as important.

In order to reduce the resistance of a charge-transfer electrode, considered is the use of a film made of a metallic material or its silicide material having a sheet resistance value of several Ω/□ which is lower by one to two orders of magnitude than silicon-system materials such as conventional polysilicon. A technology which utilized a low-resistance material whose major component is a metal among them and solved manufacturing problems caused by the material is disclosed in Japanese Patent Application No. 2003-60189 (Prior Art Document 2) for example.

FIG. 7 is a main-part outline cross-sectional view showing the charge-transfer electrode section of a solid-state imaging device disclosed in Prior Art Document 2. In FIG. 7, a charge-transfer electrode comprises a silicon-system film 31, tungsten nitride 32, and tungsten 33. Formed on the top face of the charge-transfer electrode are a silicon glass film 34, a silicon nitride film 35, and side walls 36. These films functioned as a hard mask when forming the charge-transfer electrode pattern by etching. A narrow space between electrodes is filled with an oxide film 37 and a silicon nitride film 38. Further, installed in the lower part of both ends of the charge-transfer electrode is a trapezoidal pattern 30.

In the solid-state imaging device in FIG. 7 constructed in the above manner, the resistance of the charge-transfer electrode is reduced by adopting a refractory metal such as tungsten. In addition, by installing the trapezoidal pattern 30, the silicon-system film 31 is lifted up at the edges of the charge-transfer electrode so that tungsten 33 is surrounded with the silicon-system film 31. As a result, when growing the oxide film 37 formed with a good coverage in the narrow inter-electrode spaces, tungsten 33 will not be directly exposed to a high-temperature oxidizing atmosphere, preventing abnormal expansion of tungsten 33 and breakdown of the inter-electrode spaces caused by it.

### SUMMARY OF THE INVENTION

In constructing a general solid-state image sensor shown in FIG. 5, charge-transfer electrodes need to pass not only on vertical transfer units 23 but avoid places immediately above photodiodes 22 and pass through narrow regions between vertically adjoining photodiodes 22. However, when the pattern of a solid-state image sensor is made finer, the space between the photodiodes 22 also becomes narrower, and it has become necessary for the recent pixel sizes to reduce the width passing this part of the charge-transfer electrode down to about 0.2 μm.

The structure of the conventional charge-transfer electrodes described in Prior Art Document 2 can be formed on areas such as the vertical transfer units 23 where the electrode size can remain large. However, on said extremely thin areas the structure consisting only of a high-resistance silicon-system film 31 must be adopted, and tungsten 33 cannot be formed in the center of each electrode. Therefore, even if a charge-transfer electrode is partially given a lower resistance by tungsten 33, the effect of resistance reduction becomes very small as the whole electrode, which was a problem.

The objective of the present invention is to provide a method of manufacturing a solid-state image sensor, wherein low-resistance charge-transfer electrodes can be obtained even if the pattern of the solid-state image sensor is made finer and the charge-transfer electrode can be formed without causing any manufacturing problem, and a solid-state image sensor realized by the manufacturing method.

In order to solve the above problems, the solid-state image sensor manufacturing method of the present invention comprises a process of forming photodiodes on a semiconductor substrate for photoelectrically converting incident light, a process of forming charge-transfer electrodes on said semiconductor substrate via an insulating film for transferring signal charges generated by the photoelectric conversion with said photodiodes, and a process of forming metal silicide films made of at least one of cobalt silicide film, nickel silicide film, and titanium silicide film on the top faces of said charge-transfer electrodes.

The solid-state image sensor of the present invention provides photodiodes formed on a semiconductor substrate for photoelectrically converting incident light, charge-transfer electrodes formed on said semiconductor substrate via an insulating film for transferring signal charges generated by the photoelectric conversion with said photodiodes, and metal silicide films made of at least one of cobalt silicide film, nickel silicide film, and titanium silicide film formed on the top faces of said charge-transfer electrodes.

According to the present invention, metal silicide films made of at least one of cobalt silicide film, nickel silicide film, and titanium silicide film are formed on the top faces of charge-transfer electrodes. Because these metal silicide films show low resistance close to those of pure metal films having high melting points such as tungsten film, the charge-transfer electrodes can be made low in resistance. In this manner, because charge-transfer electrodes of low resistance is realized, the propagation delay of signals is suppressed, and a high-speed operation of the solid-state image sensor is made possible. In addition, because the metal silicide films has a characteristic of having high resistance against oxidizing atmosphere unlike pure metal films, the metal silicide films can be formed over the whole top surfaces of the charge-transfer electrodes without causing any manufacturing problem, which is an advantage.

In an embodiment of the present invention, in a solid-state image sensor, a plurality of said photodiodes are arranged in a planar matrix form, and said charge-transfer electrodes are formed so as to pass between adjoining said photodiodes on said semiconductor substrate. In certain cases, said metal silicide films are formed on the whole top surfaces of said charge-transfer electrodes. Further in certain cases, the width of the part of the charge-transfer electrodes passing between adjoining said photodiodes on said semiconductor substrate is 0.1 to 0.3 μm. In these cases, the present invention has a particularly large effect on reducing the resistance of the charge-transfer electrodes. Even if a part of the charge-transfer electrodes is shrunk to 0.1 to 0.3 μm for a finer structure of the solid-state image sensor, low resistance can be maintained.

In a specific embodiment of the solid-state imaging device manufacturing method of the present invention, before performing a process of forming said metal silicide film, a process of treatment at a temperature exceeding 850° C. is performed, and after performing a process of forming said metal silicide film, a process of treatment at a temperature below 850° C. is performed. Preferably, after performing a process of forming said metal silicide, a process of treatment at a temperature below 800° C. is performed. This kind of manufacturing method prevents the occurrence of problems such that the resistance of the metal silicide film increases due to a high-temperature process. In addition, said photodiodes may be formed by introducing impurities to said semiconductor substrate by ion injection, and a process of the activation thermal treatment of said impurities may be incorporated in said process of treatment at a temperature exceeding 850° C.

### BRIEF DESCRIPTION OF THE DRAWINGS

FIGS. 1A to 1C are process cross-sectional views showing the solid-state image sensor manufacturing method of an embodiment of the present invention.

FIGS. 2A to 2C are process cross-sectional views showing the solid-state image sensor manufacturing method of an embodiment of the present invention.

FIGS. 3A to 3C are process cross-sectional views showing the solid-state image sensor manufacturing method of an embodiment of the present invention.

FIGS. 4A to 4B are process cross-sectional views showing the solid-state image sensor manufacturing method of an embodiment of the present invention.

FIG. 5 is an outline planar construction diagram of a solid-state image sensor.

FIG. 6 is a planar layout view showing a part of the pixel array of a solid-state image sensor.

FIG. 7 is an outline cross-sectional view showing an example of the conventional charge-transfer electrode structure of a solid-state image sensor.

### DETAILED DESCRIPTION OF PREFERRED EMBODIMENT

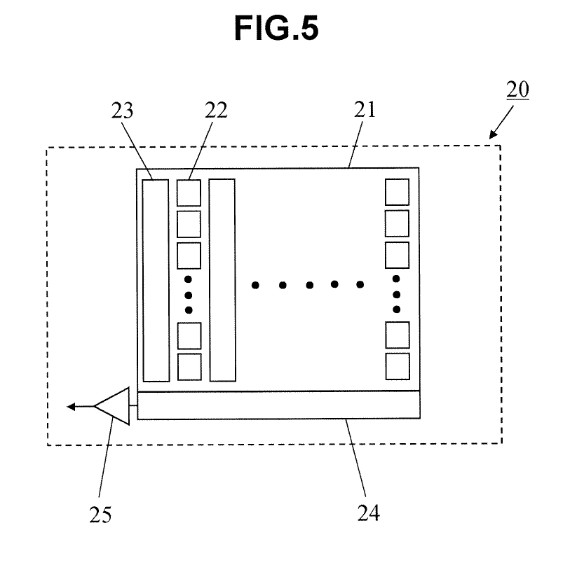

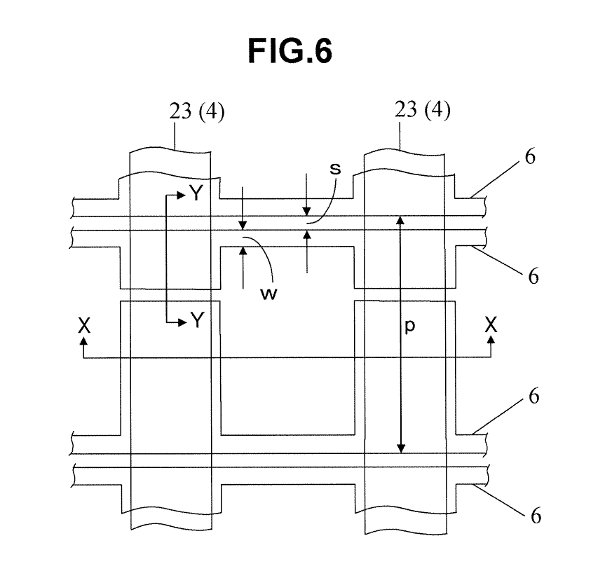

An embodiment of the present invention is explained with its specifics referring to the drawings. Adopted as the solid-state image sensor of the embodiment of the present invention is a CCD solid-state image sensor having the construction in FIG. 5 which was already explained. FIG. 6 is a planar pattern layout view showing a part of a pixel array formed in the imaging region 21 of this solid-state image sensor. In FIG. 6, four charge-transfer electrodes 6 extend horizontally, and a photodiode (not shown) is formed in the central rectangular region surrounded with the charge-transfer electrodes 6. In addition, vertical transfer units 23 are installed extending vertically under the regions wherein the width of the charge-transfer electrodes 6 is large. Omitted in FIG. 6 are light-blocking film formed on the region of pixel array along with said photodiode, various kinds of interlayer insulation films and planarized films, color filters, on-chip lenses, and the like.

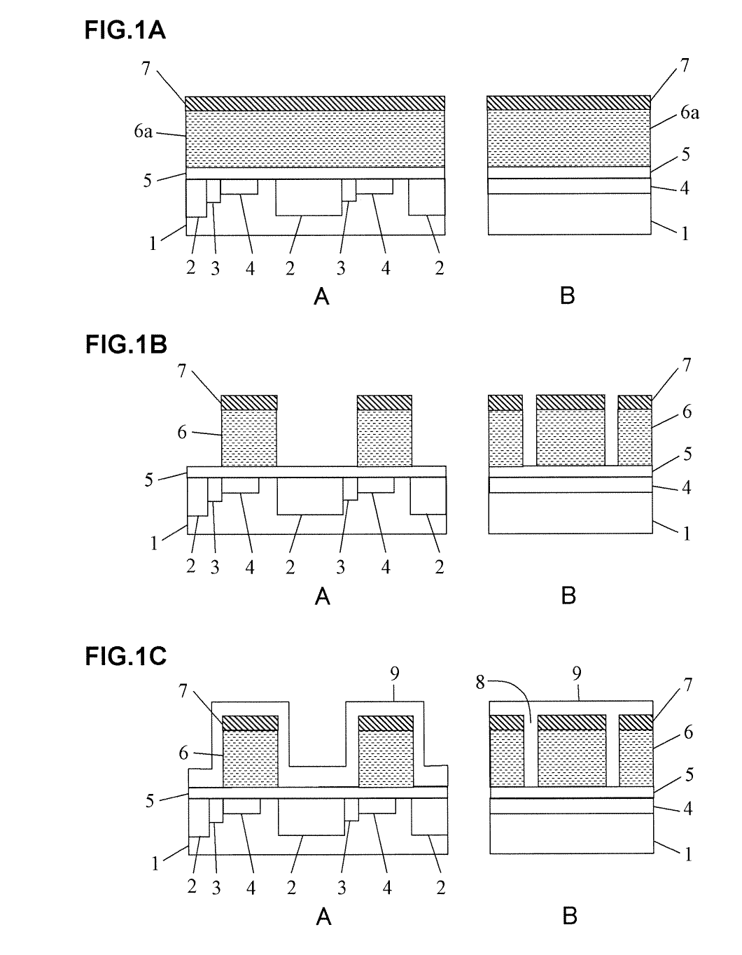

FIG. 1A to FIG. 4B are process cross-sectional views showing the solid-state image sensor manufacturing method of the embodiment of the present invention. In each of these figures, shown in the left side is a cross section along the X-X line in FIG. 6 (Section A), and shown in the right side is a cross section along the Y-Y line in FIG. 6 (Section B) together. Next, a CCD manufacturing method according to the present invention is explained using FIG. 1A to FIG. 4B.

First, as shown in FIG. 1A, an N-type photodiode 2 for photoelectrically converting incident light, a P-type separation region 3 for electrically separating individual pixels, and an N-type vertical transfer unit 4 for vertically transferring signal charges generated in the photodiode 2 are formed on a P-type semiconductor substrate (silicon) 1 for example by a conventional method such as an ion injection. Afterwards, a gate insulation film 5 having a film thickness of 40 nm is formed on the surface of the semiconductor substrate 1, and a silicon-system film 6a (film thickness of about 150 nm) such as a polysilicon film or an amorphous silicon film containing impurities such as phosphorus, and a silicon oxide film 7 (film thickness of 50 to 100 nm) are further formed in order on the gate insulation film 5 using the CVD method for example.

Next, as shown in FIG. 1B, a resist pattern (not shown) is formed on a silicon oxide film 7 using the conventional lithography technology, and using this resist pattern as a mask, the silicon oxide film 7 and the silicon-system film 6a are selectively removed by anisotropic dry etching. Then, the resist pattern is removed, forming charge-transfer electrodes 6. In this embodiment, a resist pattern was used for forming the charge-transfer electrodes 6. However, according to the method described in Prior Art Document 2, the following method is allowed. A pattern is formed on the silicon oxide film 7 on the silicon-system film 6a, side walls comprising of an insulation film such as a silicon oxide film and a silicon nitride film is added to expand the pattern size, and the silicon-system film 6a is etched with the expanded pattern as a hard mask. By so doing, in Section B the interval of the charge-transfer electrodes 6 can be formed very narrow. In short, the charge-transfer electrodes 6 only need a silicon oxide film formed on them. In this process, while the charge-transfer electrodes 6 are formed, in the peripheral circuit section outside the pixel array region, the gate electrode of a MOS-type transistor is also formed with the silicon-system film 6a.

Afterwards, in order to adjust the charge-transfer potential in a region (Section B) of the silicon substrate 1 located in a narrow interval of the charge-transfer electrodes 6 when the solid-state image sensor is operating, impurities are introduced to this region by ion injection for example. In the peripheral circuit section, in order to form the low-concentration and high-concentration source/drain, impurities are introduced to the silicon substrate 1 by ion injection for example.

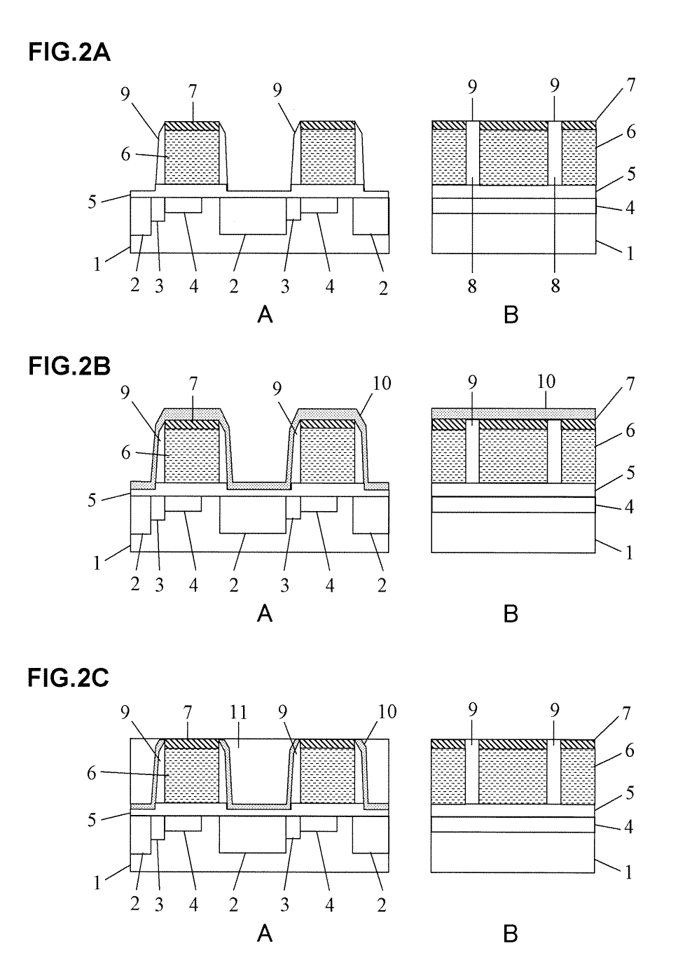

Next, as shown in FIG. 1C, a silicon oxide film 9 is formed. The film thickness of the silicon oxide film 9 is a film thickness wherein a narrow space 8 (corresponding to s in FIG. 6, where s=0.1 to 0.3 μm for example) between the charge-transfer electrodes 6 on the section B cross section is embedded, and a concave section corresponding to the shape of the charge-transfer electrodes 6 is formed on the section A cross section. This silicon oxide film 9 is preferably deposited using the CVD method at a high temperature exceeding 850° C. so that a good step coverage of such a degree that the space 8 can be embedded. Afterwards, as shown FIG. 2A, whole surface anisotropic etching is applied to the silicon oxide film 9 using an etchback method. Removed by this etching are a part of the silicon oxide film 9 formed on the gate insulating film on the section A cross section, and a part of the silicon oxide film 9 formed on the silicon oxide film 7 on the section B cross section. As a result, the silicon oxide film 9 is embedded in the space 8 of the section B, and at the same time side walls of the silicon oxide film 9 are formed on the side walls of the charge-transfer electrodes 6 on the section A.

Afterwards, P-type impurities are injected to the upper part of the photodiode 2 using ion injection, forming an impurity layer such as a P-type positive charge accumulation layer (not shown), and the activation thermal treatment of the injected impurities is performed at a temperature exceeding 850° C. and below 900° C. within a time range of 10 to 60 minutes. By this thermal treatment, the photodiode 2 formed by ion injection so far, injected impurities in the impurity layers such as the vertical transfer unit 4, and injected impurities in the peripheral circuit section are simultaneously activated. For the impurity activation thermal treatment, a rapid thermal annealing (RTA) for about 10 to 60 seconds may be employed.

Next, as shown in FIG. 2B, a silicon nitride film 10 used as an antireflective film for incident light onto the photodiode 2 is formed with a thickness of 50 nm. Afterwards, as shown in FIG. 2C, a resist film 11 is coated over the whole surface as to fill in between the charge-transfer electrodes 6 on the section A at least, and the resist film 11 and the silicon nitride film 10 are uniformly removed by etching using an etchback method by dry etching. In this manner, the silicon oxide film 7 is exposed on the charge-transfer electrodes 6. At this time, because the silicon oxide film 9 fills between the charge-transfer electrodes 6 on the section B, etching there is prevented. The etchback of the silicon oxide film 9 in the process of FIG. 1C and the etchbacks of the resist film 1 and the silicon nitride film 10 in the process of FIG. 2C stop when the silicon oxide film 7 becomes exposed, the silicon oxide 7 is formed in the first place with such a film thickness that the charge-transfer electrodes 6 are not exposed by these etchbacks (the process of FIG. 1A).

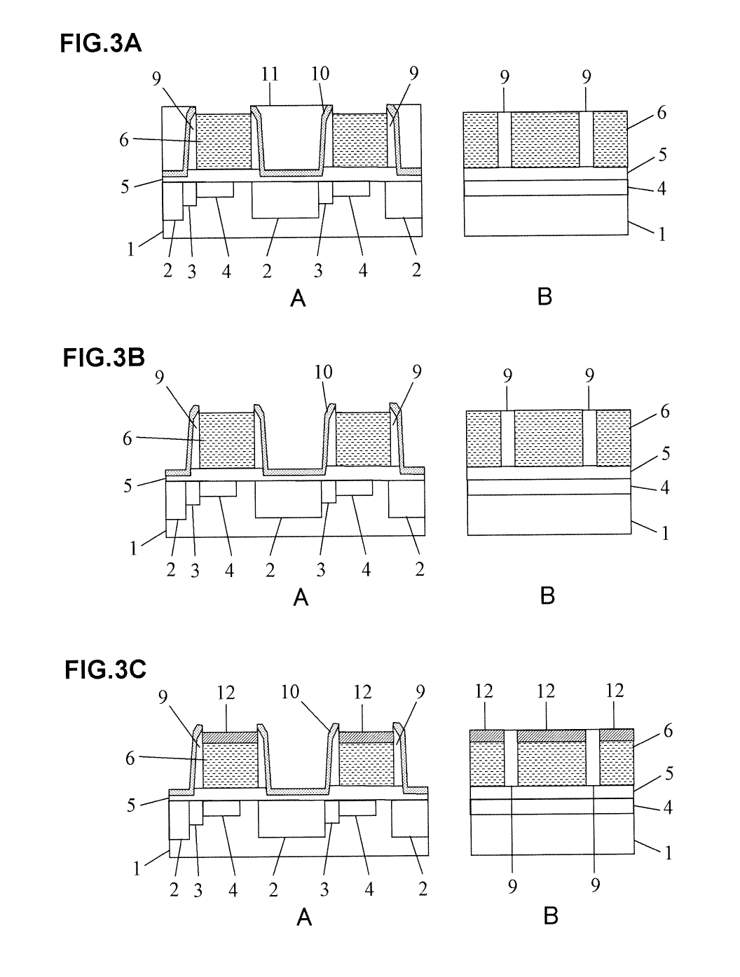

Next, as shown in FIG. 3A, leaving the resist film 11 as it is, the silicon oxide film 7 is etched to expose the upper part of the charge-transfer electrodes 6. Afterwards, as shown in FIG. 3B, the resist film 11 is removed. Thereby, the region excluding the top face of the charge-transfer electrodes 6 becomes covered with the silicon nitride film 10. Next, as shown in FIG. 3C, a thin cobalt film (not shown) is deposited over the whole surface, a first thermal treatment is performed by RTA at a temperature range of 450 to 600° C. This thermal treatment has silicon-system film, which is the component materials of the charge-transfer electrodes 6, and cobalt film react with each other in the exposed part, forming a cobalt silicide (CoSiₓ) film 12. Then, unreacted cobalt film remaining in the region other than those on the charge-transfer electrodes 6 is selectively removed by wet etching. Afterwards, a second thermal treatment is further performed at about 700° C. by RTA to stabilize the crystalline state of the cobalt silicide film 12 and reduce its resistance at the same time. The film thickness of the cobalt silicide film 12 becomes 10 to 50 nm (Standard: about 20 nm) after all.

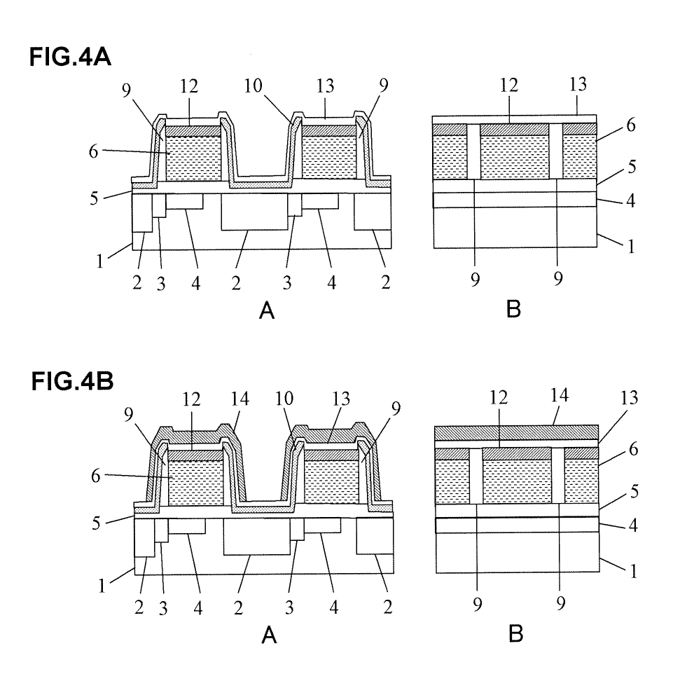

Next, as shown in FIG. 4A, a silicon oxide film 13 as an interlayer insulating film is formed. Next, as shown in FIG. 4B, a refractory metal film such as tungsten film is deposited on the silicon oxide film 13, and further using a resist pattern (not shown) formed on it as a mask, the high melting point metal film is selectively etched to make it patterned, and a light-blocking film 14 having an opening immediately above the photodiode 2 is formed. After this process, formed on the whole surface including on the light-blocking film 14 are an insulating film comprising of silicon oxide film for example, various kinds of wirings having Al as the main component, a passivation film, and the like. Afterwards, a color filter is further formed in a layer above them, and an on-chip lens is formed on the photodiode 2, in other words, on the color filter in the position opposing an optical sensor unit. If necessary, it may be made a structure wherein an intralayer lens and an optical waveguide are formed as an optical layer. In this manner, even after forming the cobalt silicide film 12 in the process of FIG. 3C, multiple processes are performed. All those processes, especially the processes taking 10 minutes or longer in the treatment time, are all performed at 850° C. or lower in temperature. Further, they should preferably be performed at 800° C. or lower in temperature.

In the solid-state image sensor manufacturing method according to the present invention, a cobalt silicide film 12 is formed over the whole area of the top faces of the charge-transfer electrodes 6 as in the process of FIG. 3C. In the pixel pattern layout (FIG. 6), if a solid-state image sensor of a scale wherein the periodic array pitch p of the charge-transfer electrodes 6 becomes about 1.2 μm is assumed, the minimum width w of the charge-transfer electrodes 6 passing on regions between adjoining photodiodes is reduced to 0.1 to 0.3 μm. However, the cobalt silicide film 12 is formed even on such a part by the present invention. Furthermore, cobalt silicide has a specific resistance of 20 μΩ·cm, showing a similarly low resistance to that of tungsten (specific resistance 14 μΩ·cm) used in the conventional solid-state image sensors such as the one in Prior Art Document 2. Based on these, by the present invention, unlike the technology described in Prior Art Document 2 for example, fine width parts of electrodes never become extremely high in resistance, thus preventing the propagation delay of image signals.

Shown in the embodiment according to the present invention was a case of applying cobalt silicide onto the surfaces of the charge-transfer electrodes 6. As other metal silicides showing similarly low resistances to metals, nickel silicide (NiSiₓ: Specific resistance 18 μΩ·cm) and titanium silicide (TiSiₓ: Specific resistance 20 μΩ·cm) may also be used. These low resistance metal silicide films have a problem that at a high temperature exceeding 850° C. agglomeration tends to occur wherein the metal phase and the silicon phase are separated to increase the resistance, and that caused by the increase in the film stress due to high temperature, when an electrode pattern is formed, narrow parts tend to be cut off.

However, by the manufacturing method according to the present invention, all high-temperature treatment processes exceeding 850° C. (including the deposition of the silicon oxide film 9 and the activation thermal treatment of impurity layers such as the photodiode 2, the separation region 3, the vertical transfer units 4, and the source/drain of MOS transistors installed in the peripheral circuit section) are performed before forming a metal silicide film on the surfaces of the charge-transfer electrodes 6. After forming a metal silicide film, all the processes are performed at the temperatures and times, especially below 850° C. in temperature, wherein its resistance falls within the tolerated values for the solid-state image sensor operation characteristics, or no line cut-off occurs. Therefore, problems in the manufacturing processes can be prevented.

As metal silicide materials, other than those listed above, tungsten silicide (WSiₓ), molybdenum silicide (MoSiₓ), tantalum silicide (TaSiₓ), platinum silicide (PtSiₓ), and the like may be used according to the specifications such as the resistance value, the charge-transfer electrode width, and the heat-resistant temperature required to the solid-state image sensor.

The solid-state image sensor manufacturing method of the present invention has various other advantages than achieving the above effects. First, as shown in FIG. 3C, after covering the photodiode 2 with the silicon nitride film 10 as an antireflective film, the metal silicide film 12 is formed. Through this process, especially its metal elements included in the silicide film 12 can be prevented from contaminating the photodiode 2, and thus white scratches on images displayed by the solid-state image sensor due to the contamination can be prevented. Therefore, no special measures against white scratches or changes in thermal treatment conditions or thermal treatment processes are necessary.

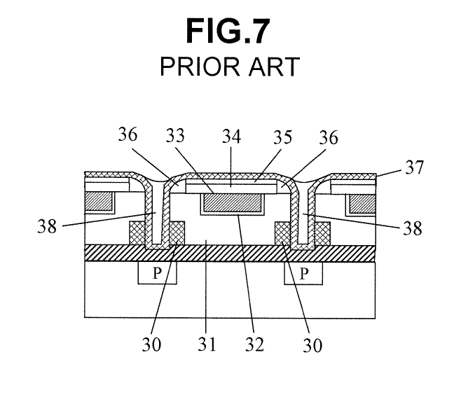

In addition, when embedding the silicon oxide film 9 in the narrow space 8 (Section B) with the silicon oxide film 7 left, as shown in the process of FIG. 2C, the surface can be mostly flattened in comparison with a conventional embedded silicon oxide film 38 in FIG. 7. In the solid-state image sensor, there exists a region, although not shown in FIG. 4B, wherein the narrow space 8 between the charge-transfer electrodes 6 is formed, but the light-blocking film 14 is not formed. Because of the flattened surface of the region, even if a refractory metal film etching is performed for forming the pattern of the light-blocking film 14 in the region wherein the light-blocking film 14 is not formed, it is prevented that a etching residue of the refractory metal film occurs along the space 8, causing patterns like a short circuit, and making an incomplete pattern of the light-blocking film 14.

Furthermore, as shown in FIG. 4B, the silicon oxide film 13 which insulates between the charge-transfer electrodes 6 and the light flocking layer 14 is primarily set thin. As in FIG. 7, if an embedded film (the silicon nitride film 38) forms a concave section, on this concave section the silicon oxide film 13 is formed even thinner, and the withstand voltage between the charge-transfer electrodes and the light-blocking film with a specified voltage applied decreases. Then, if a concave section is formed in the above mentioned region wherein the space 8 is formed but the light-blocking film 14 is not formed, a thin etching residue of the refractory metal film occurs, which connects to the light-blocking film along the space 8. Because this residue is thin, an electric field generated between the charge-transfer electrodes and the residue becomes higher especially in the residue side, the withstand voltage between the charge-transfer electrodes and the light-blocking film may decrease. As opposed to this, according to the present invention, because the embedded silicon oxide film 9 is made to be flat, such an event never occurs. In addition, the silicon oxide film 9 has a lower film stress than that of the silicon nitride film 38 used as an embedded film of the solid-state image sensor in FIG. 7, the dark current of the solid-state image sensor caused by stress can be reduced. Because an oxidation-resistant metal silicide film instead of the conventional metal film (such as tungsten) is used as a low-resistance layer formed on the charge-transfer electrodes 6 in the present invention, there is no need to form a protective film (films 34, 35, and 36 in FIG. 7 for example) on it against a high-temperature oxidizing atmosphere, reducing the height of the charge-transfer electrodes 6. Therefore, the area of the light-blocking film 14 on the side wall section of the charge-transfer electrodes 6 (see FIG. 4B) can be reduced. As a result, a part of incident light which is reflected by said light-blocking film 14 on the side-wall section after entering from the exterior though an on-chip lens and does not reach the photodiode 2 can be reduced. Thus, the sensitivity decline of the solid-state image sensor can be suppressed.

The present invention maximizes the area of a low-resistance layer formed on the surface of charge-transfer electrodes to improve the low resistance property of the electrodes and is effective for solid-state image sensors which operate at a high speed and have fine pixels.

What is claimed is:

1. A solid-state image sensor manufacturing method comprising
a process of forming photodiodes on a semiconductor substrate for photoelectrically converting incident light;
a process of forming charge-transfer electrodes on said semiconductor substrate via an insulating film for transferring signal charges generated by the photoelectric conversion with said photodiodes;
and a process of forming metal silicide films made of at least one of cobalt silicide film, nickel silicide film, and titanium silicide film on the top faces of said charge-transfer electrodes.

2. The solid-state image sensor manufacturing method according to claim 1, wherein a plurality of said photodiodes are arranged in a planar matrix form, and said charge-transfer electrodes are formed so as to pass between adjoining said photodiodes on said semiconductor substrate.

3. The solid-state image sensor manufacturing method according to claim 1, wherein said metal silicide films are formed on the whole top surfaces of said charge-transfer electrodes.

4. The solid-state image sensor manufacturing method according to claim 2, wherein said metal silicide films are formed on the whole top surfaces of said charge-transfer electrodes.

5. The solid-state imaging device manufacturing method according to claim 3, wherein before performing a process of forming said metal silicide film, a process of treatment at a temperature exceeding 850° C. is performed, and after performing a process of forming said metal silicide film, a process of treatment at a temperature of 850° C. or less is performed.

6. The solid-state imaging device manufacturing method according to claim 4, wherein before performing a process of forming said metal silicide film, a process of treatment at a temperature exceeding 850° C. is performed, and after performing a process of forming said metal silicide film, a process of treatment at a temperature of 850° C. or less is performed.

7. The solid-state imaging device manufacturing method according to claim 5, wherein after performing a process of forming said metal silicide, a process of treatment at a temperature of 800° C. or less is performed.

8. The solid-state imaging device manufacturing method according to claim 6, wherein after performing a process of forming said metal silicide, a process of treatment at a temperature of 800° C. or less is performed.

9. The solid-state imaging device manufacturing method according to claim 5, wherein
said photodiodes are formed by introducing impurities to said semiconductor substrate by ion injection, and said process of treatment at a temperature exceeding 850° C. includes a process of the activation thermal treatment of said impurities.

10. The solid-state imaging device manufacturing method according to claim 6, wherein
said photodiodes are formed by introducing impurities to said semiconductor substrate by ion injection, and said process of treatment at a temperature exceeding 850° C. includes a process of the activation thermal treatment of said impurities.

11. A solid-state image sensor, wherein provided are
photodiodes formed on a semiconductor substrate for photoelectrically converting incident light;
charge-transfer electrodes formed on said semiconductor substrate via an insulating film for transferring signal charges generated by the photoelectric conversion with said photodiodes;
and metal silicide films made of at least one of cobalt silicide film, nickel silicide film, and titanium silicide film on the top faces of said charge-transfer electrodes.

12. The solid-state image sensor according to claim 11, wherein a plurality of said photodiodes are arranged in a planar matrix form, and said charge-transfer electrodes are formed so as to pass between adjoining said photodiodes on said semiconductor substrate.

13. The solid-state image sensor according to claim 11, wherein said metal silicide films are formed on the whole top surfaces of said charge-transfer electrodes.

14. The solid-state image sensor according to claim 12, wherein said metal silicide films are formed on the whole top surfaces of said charge-transfer electrodes.

15. The solid-state image sensor according to claim 14, wherein the width of the part of the charge-transfer electrodes passing between adjoining said photodiodes on said semiconductor substrate is 0.1 to 0.3 μm.
